(19) United States
(12) Patent Application Publication
(10) Pub. No.: US 2002/0110993 A1
(43) Pub. Date: Aug. 15, 2002

(54) Method for forming an electrode with a layer of hemispherical grains thereon

(76) Inventors: Wengyi Chen, Chu-Pei City (TW); Chiuling Lee, Hsin-Chu City (TW)

Correspondence Address: Powell, Goldstein, Frazer & Murphy, LLP, Suite 600, 1001 Pennsylvania Avenue, Washington, DC, 20004, US

(21) Appl. No.: 09/783,873

(22) Filed: Feb. 15, 2001

(51) Int. Cl. H01L 21/20; H01L 21/44

(52) U.S. Cl. 438/398; 438/684

(57) ABSTRACT

A method for forming an electrode of a capacitor in a dynamic random access memory comprises providing a semiconductor structure having a dielectric layer thereon. At least a first conductive node is formed on and in the dielectric layer, which is primarily comprised silicon. A second conductive layer is formed at a sidewall of the first conductive node, and multitudes of hemispherical silicon grains are formed on the second conductive layer. The hemispherical silicon grains grown on the second conductive layer can have a well-controlled thickness.

### BACKGROUND OF THE INVENTION

1. Field of the Invention

The invention relates to an electrode of a capacitor, and more particularly to an electrode with a layer of hemispherical grains thereon.

2. Description of the Prior Art

As the size of various geometric features of semiconductor devices are reduced, new problems arise which must be solved in order to continue to economically and reliably produce integrated circuit chips.

As an example, DRAM memory structures are one type of integrated circuit for which problems must be overcome in order to achieve increased miniaturization and integration levels. A capacitor generally includes two electrodes and a dielectric layer between these two electrodes. In order to increase capacitance, either the dielectric thickness is reduced or the electrode area is increased. One of methods of increasing the electrode area is to use a polysilicon layer with a selective HSG layer (S-HSG) on its top surface as a lower electrode. The use of S-HSG grain, silicon layer, as the surface layer of a storage node electrode, has allowed increases in DRAM cell capacitance to be realized. The concave and convex features of the S-HSG silicon layer, result in surface area increases, when compared to counterparts fabricated with smooth surfaces. However, the S-HSG layer is not easily formed on the polysilicon layer. If the storage node is formed by the S-HSG layer on the doped polysilicon layer, the S-HSG layer may be poor in quality or may even not be formed. Alternatively, the formation of the S-HSG on an amorphous silicon layer is another choice. The attainment of the S-HSG silicon layer usually features the formation of S-HSG silicon seeds followed by an anneal cycle. The formation of the S-HSG silicon layer is by the consumption of the S-HSG silicon seeds and a top portion of the underlying silicon storage node shape.

As FIG. 1A, a silicon substrate 100 is provided and multitudes of gate structures 110 are formed thereon. An inter-silicon oxide layer 120 is then deposited over the silicon substrate 100 and the gate structures 110. Next, a storage node pattern is transferred into the inter-silicon oxide layer 120 and then the inter-silicon oxide layer 120 is etched to form multitude of storage openings. Next, an amorphous silicon layer is filled into the storage openings and covered over the inter-silicon oxide layer 120. Then some storage nodes 130 are formed by etching the amorphous silicon layer. The space between the storage nodes 130 is “X” as shown in FIG. 1A.

FIG. 1B is a top-view diagram of the FIG. 1A. The space “X” needs to be large enough so that prevents the storage nodes 130 from short. Next, depicted in FIG. 2A, in order to raise the capacitance of the storage node 130, the S-HSG layer is formed on the storage nodes 130. The concave and convex features of the S-HSG silicon layer results in surface area increases of the storage nodes 130. Similarly, FIG. 2B is a top-view diagram of the FIG. 2A. To be specific, the concave and convex features make the space “X” is smaller in FIG. 2A than in FIG. 1A.

However, the conventional methods described above mainly have some disadvantages. When the S-HSG layer is formed on the amorphous silicon layer, those S-HSG silicon seeds are easy to migrate into the amorphous silicon layer so that the growth thickness of the S-HSG layer is hard to control. Thus, the uncontrolled growth of the S-HSG layer may cause the narrow spaces between the storage nodes, and further result in the short of the storage nodes. Moreover, the critical dimension utility of the photolithography is restricted under consideration to the uncontrolled growth of the S-HSG layer.

Thus, if the growth and migration of the S-HSG layer can be controlled and limited within a desire range, the short of the storage node can be reduced. Moreover, the critical dimension utility of the photolithography may not be restricted and further fits into higher integrity desires.

### SUMMARY OF THE INVENTION

It is an object of the present invention to provide a method for forming an electrode of a capacitor in a dynamic random access memory. The hemispherical silicon grains grown on the storage electrode can have a well-controlled thickness.

It is another object of the present invention to provide a method for controlling growth thickness of a HSG silicon layer on an electrode. The growth thickness of the HSG silicon layer can be restricted by a polysilicon storage node or a thin silicon oxide film on an amorphous silicon storage node.

It is a further object of the present invention to provide a method for raising a critical dimension utility of photolithography for formation of an electrode. A well-controlled thickness of the HSG silicon layer applied on the formation of the electrode may utilize the critical dimension without consideration of short problem resulted in uncontrolled thickness of the HSG silicon layer.

In the present invention, a method for forming an electrode of a capacitor in a dynamic random access memory comprises providing a semiconductor structure having a dielectric layer thereon. At least a first conductive node is formed on and in the dielectric layer, which is primarily comprised silicon. A second conductive layer is formed at a sidewall of the first conductive node, and multitudes of hemispherical silicon grains are formed on the second conductive layer.

### BRIEF DESCRIPTION OF THE DRAWINGS

A better understanding of the invention may be derived by reading the following detailed description with reference to the accompanying drawing wherein:

FIG. 1A is a cross-sectional schematic diagram illustrating the formation of the storage nodes in accordance with the conventional method;

FIG. 1B is a top-view schematic diagram of FIG. 1A;

FIG. 2A is a cross-sectional schematic diagram following FIG. 1A illustrating the formation of the HSG silicon layer on the storage nodes in accordance with the conventional method;

FIG. 2B is a top-view schematic diagram of FIG. 2A;

FIG. 3A is a cross-sectional schematic diagram of the first embodiment illustrating the formation of the polysilicon storage nodes in accordance with the present invention;

FIG. 3B is a top-view schematic diagram of FIG. 3A;

FIG. 4 is a cross-sectional schematic diagram of the first embodiment illustrating the formation of an amorphous layer following the step of FIG. 3;

FIG. 5A is a cross-sectional schematic diagram of the first embodiment illustrating the next step of FIG. 4;

FIG. 5B is a top-view schematic diagram of FIG. 5A;

FIG. 6A is a cross-sectional schematic diagram of the first embodiment illustrating the formation of the HSG silicon layer next to FIG. 5A;

FIG. 6B is a top-view schematic diagram of FIG. 6A; and

FIGS. 7A through 7D are a series of the cross-sectional schematic diagrams illustrating the formation of amorphous silicon storage nodes with the HSG silicon layer thereon of the other embodiment in accordance with the present invention.

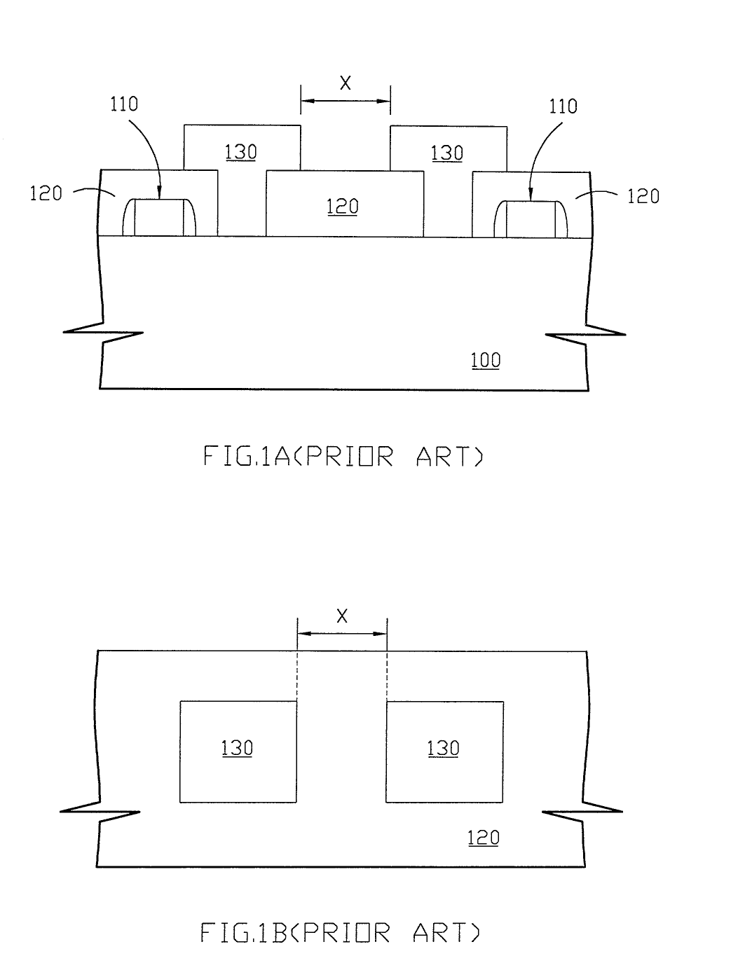

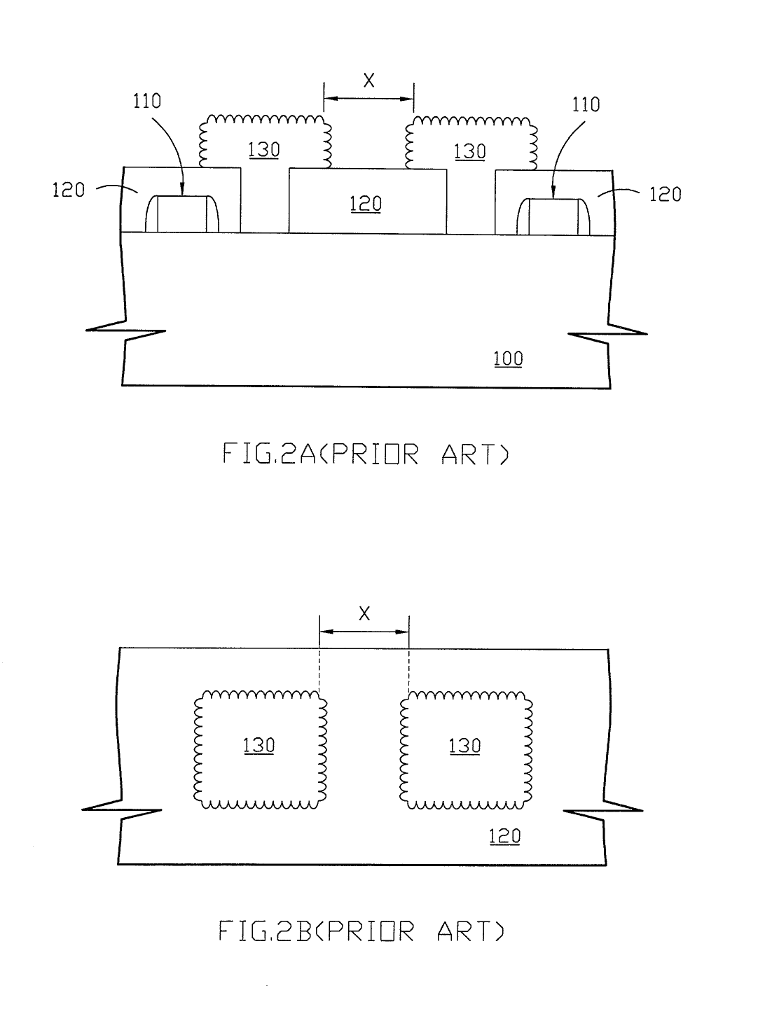

### DESCRIPTION OF THE PREFERRED EMBODIMENT

The semiconductor devices of the present invention are applicable to a board range of semiconductor devices and can be fabricated from a variety of semiconductor materials. While the invention is described in terms of a single preferred embodiment, those skilled in the art will recognize that many steps described below can be altered and that species and types of substrate and dopant as well as other materials substitutions can be freely made without departing from the spirit and scope of the invention.

Furthermore, there is shown a representative portion of a semiconductor structure of the present invention in enlarged, cross-sections of the two dimensional views at several stages of fabrication. The drawings are not necessarily to scale, as the thickness of the various layers are shown for clarify of illustration and should not be interpreted in a limiting sense. Accordingly, these regions will have dimensions, including length, width and depth, when fabricated in an actual device.

In the present invention, a method for forming an electrode of a capacitor with a layer of hemispherical silicon grains comprises providing a semiconductor structure having a dielectric layer thereon. At least a polysilicon storage node is formed on and in the dielectric layer. An amorphous silicon layer is formed at a sidewall of the polysilicon storage node, and the layer of hemispherical silicon grains is formed on the amorphous silicon layer. A method for controlling a thickness of a layer of hemispherical silicon grains for an electrode comprises providing a semiconductor structure having a dielectric layer thereon. At least a conductive storage node is formed on and in the dielectric layer, which is primarily comprised silicon. A thin oxide film is formed over the dielectric layer and the d conductive storage node. An amorphous silicon layer is formed at a sidewall of the conductive storage node, and the layer of hemispherical silicon grains is formed on the amorphous silicon layer and on a top surface of the conductive storage node.

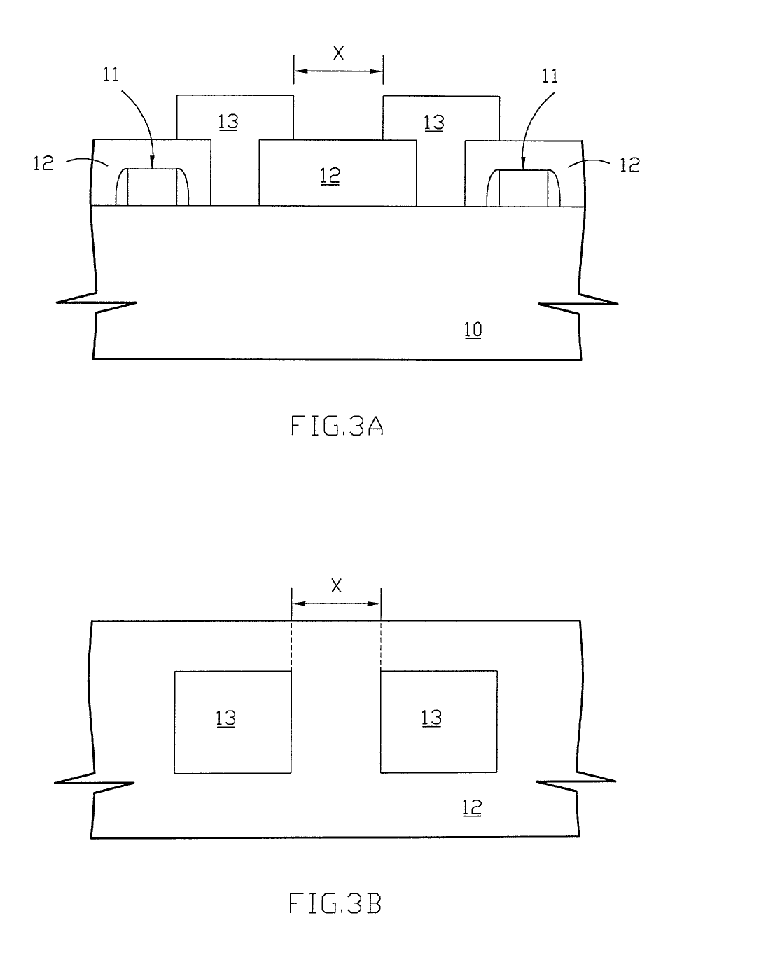

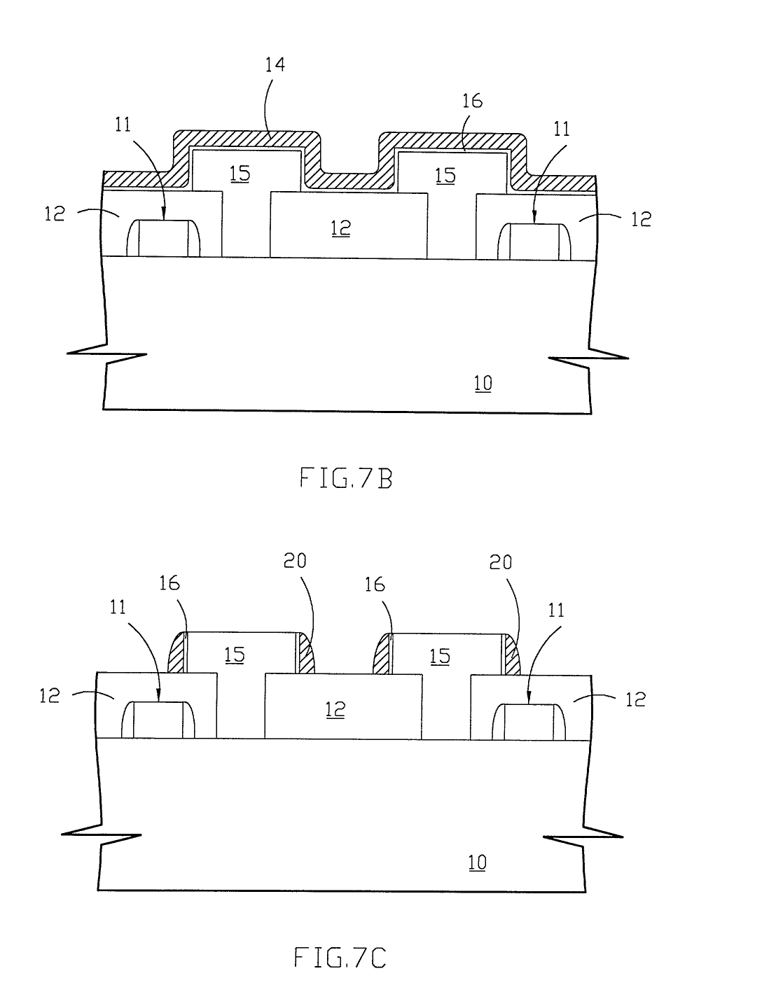

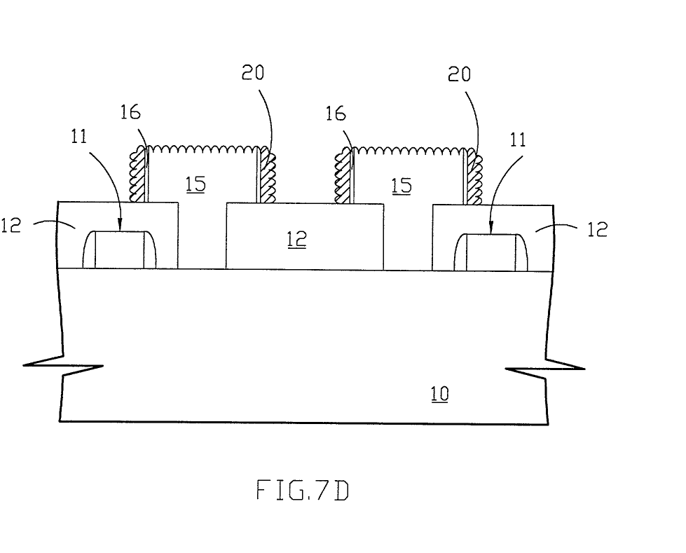

There are two embodiments introduced illustrating the present invention; one is an embodiment of the polysilicon storage node; and the other is an embodiment of the amorphous silicon storage node in accordance with the present invention. The embodiment of the polysilicon storage node is illustrated with FIG. 3A through FIG. 6B, and the other embodiment of the amorphous silicon storage node with FIG. 7A through FIG. 7D.

First depicted in FIG. 3A, a silicon substrate 10 is provided and multitudes of gate structures 11 are formed thereon. A dielectric layer, such as an inter-silicon oxide layer 12, is covered on the silicon substrate 10 and the gate structures 11. Multitudes of conductive nodes, such as polysilicon storage nodes 13, are formed on and in the inter-silicon oxide layer 12 by the conventional methods, such as pattern transfer and etch. The space between the polysilicon storage nodes 13 is represented as “X”. A top-view schematic diagram of FIG. 3A is shown in FIG. 3B. Moreover, the word-line structures may be formed in the embodiment, but they aren't shown in FIG. 3A and FIG. 3B.

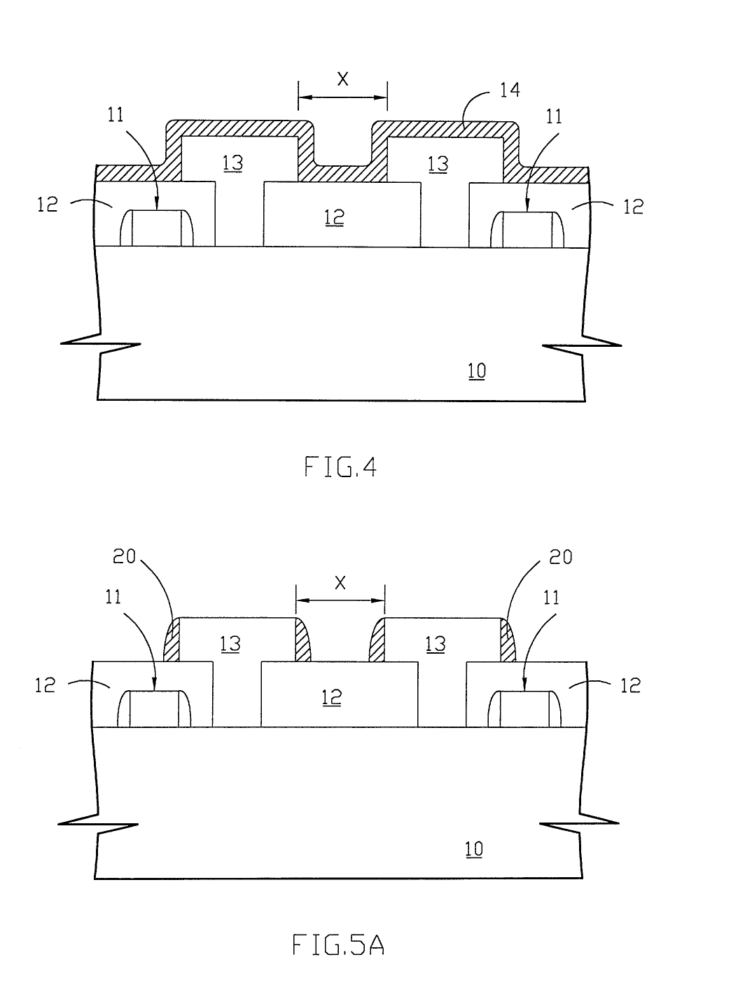

Next, as shown in FIG. 4, because the selective HSG layer is not easily formed on the polysilicon layer, an amorphous silicon layer 14 is first deposited over the inter-silicon oxide layer 12 and the polysilicon storage nodes 13. The deposited thickness of the amorphous silicon layer 14 is about from 50 through 900 angstroms, dependent on the desired space “X”. Then depicted in FIG. 5A, with the polysilicon storage nodes 13 as self aligned pattern, the amorphous silicon layer 14 is blanket etched back to form an amorphous silicon “spacer” 20 at sidewalls of the polysilicon storage nodes 13. As shown in FIG. 5B, the width of the amorphous silicon spacer is “t”. Because of the formation of the amorphous silicon spacer 20, the perimeter and volume of the polysilicon storage nodes 13 are increased and whereby further increase the capacitance of the polysilicon storage nodes 13.

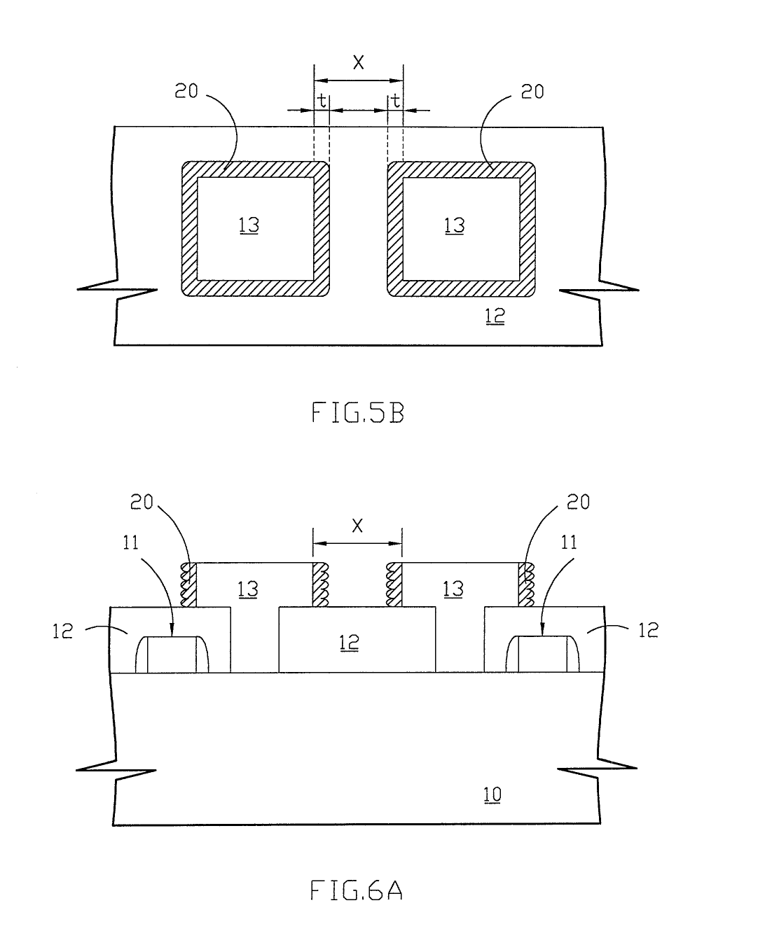

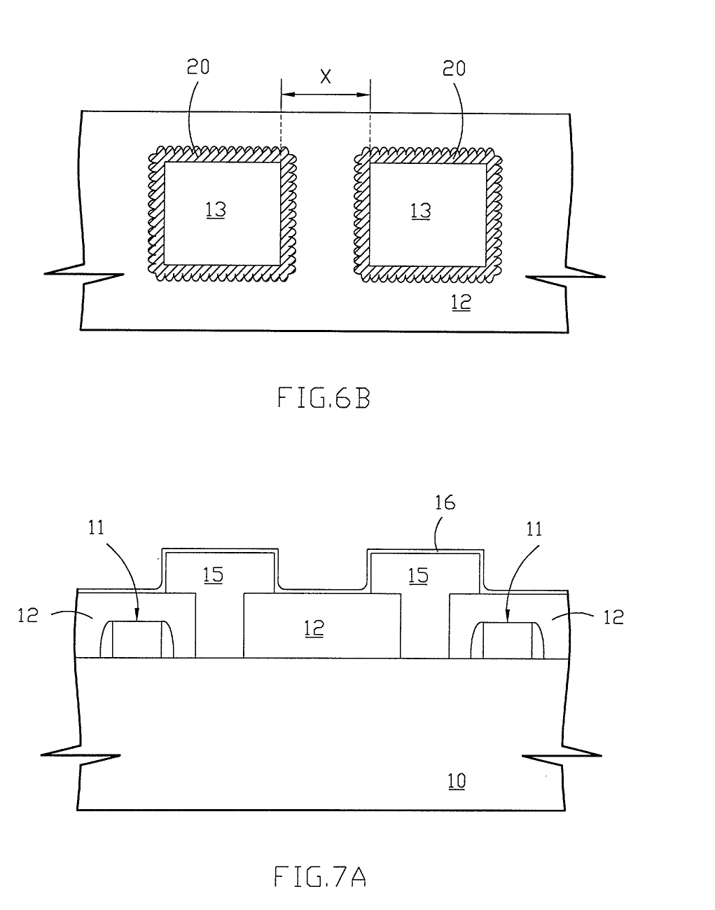

Next, depicted in FIG. 6A, the concave and convex grains of HSG silicon layer are formed on the amorphous silicon spacer 20 by the conventional methods. Because the HSG silicon layer is not easy to form on the polysilicon layer, there is no HSG silicon layer on the top surface of the polysilicon storage nodes 13. On the other hand, the HSG silicon layer is restrictedly grown on the limited width of the amorphous silicon spacer 20, thus the growth width of the HSG silicon layer is well controlled. The well-controlled growth of the HSG silicon layer may reduce the short probability of the polysilicon storage nodes 13. Moreover, because the growth width of the HSG silicon layer is well controlled, the critical dimension of precedent photolithography for formation of the storage node can be improved without consideration of short problem resulted from the uncontrolled HSG silicon layer. As shown in FIG. 6B, the HSG silicon layer is only on the amorphous silicon spacer 14, and the top surface of the polysilicon storage nodes 13 is exposed outside.

The other embodiment of the present invention is shown from FIG. 7A through FIG. 7D. Sometimes for other requirements, the storage nodes need to be made of amorphous silicon, shown in FIG. 7A. Similarly, the silicon substrate 10 is provided and multitudes of gate structures 11 are formed thereon. The inter-silicon oxide layer 12 is covered on the silicon substrate 10 and the gate structures 11. Multitudes of amorphous silicon storage nodes 15 are formed on and in the inter-silicon oxide layer 12. Then a thin silicon oxide film 16 is formed over on the inter-silicon oxide layer 12 and the amorphous silicon storage nodes 15. The formation of the thin silicon oxide film 16 is implemented by any conventional method, such as thermal oxidation or chemical oxidation during clean procedure, etc. In this embodiment, the thickness of the thin silicon oxide film 16 is within 10 angstroms.

Next, shown in FIG. 7B, the amorphous silicon layer 14 is first deposited on the thin silicon oxide film 16. Then the amorphous silicon layer 14 and the thin silicon oxide film 16 are blanket etched back to remain the portions on the sidewalls of the amorphous silicon storage nodes 15, shown in FIG. 7C. To be specific, the thin silicon oxide film 16 between the amorphous silicon storage node 15 and the amorphous silicon spacer 20 is remained.

Then the concave and convex grains of HSG silicon layer are formed on the amorphous silicon spacer 20 and the top surface of the amorphous silicon storage nodes 15, shown in FIG. 7D. To be specific, the growth thickness of the HSG silicon layer is restricted by the thin silicon oxide film 16 and the HSG silicon seeds don't migrate into the amorphous silicon storage nodes 15, thus the growth of the HSG silicon layer is still well controlled in this embodiment of the present invention. Moreover, because of the amorphous silicon material, the HSG silicon layer may be formed on the top surface of the amorphous storage node 15 and further increase the capacitance of the amorphous storage node 15 without reducing the critical dimension of the photolithography.

It is one object of the present invention to control the growth thickness of the HSG silicon layer on the storage node. The application of the polysilicon “core” can prevent the HSG silicon layer from over-migration and over-growth. The alternative method is to form an interface, such as the thin silicon oxide film in the second embodiment, between the amorphous silicon “core” and the exterior amorphous silicon layer.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for forming an electrode of a capacitor in a dynamic random access memory, said method comprising:
providing a semiconductor structure having a dielectric layer thereon;
forming at least a first conductive node on and in said dielectric layer, said first conductive node primarily comprising silicon;
forming a second conductive layer at a sidewall of said first conductive node; and
forming a plurality of hemispherical silicon grains on said second conductive layer.

2. The method according to claim 1, wherein said forming step of said second conductive layer comprises:
depositing said second conductive layer on said dielectric layer and said first conductive node; and
etching back said second conductive layer to remain said second conductive layer at said sidewall of said first conductive node.

3. The method according to claim 1, wherein said second conductive layer comprises an amorphous silicon layer.

4. The method according to claim 1, wherein said first conductive node comprises a polysilicon node.

5. The method according to claim 1, wherein said first conductive node comprises an amorphous silicon node used for said electrode of said capacitor.

6. The method according to claim 5, wherein said first conductive node further comprises a thin oxide layer at said sidewall and whereby said thin oxide layer is between said first conductive node and said second conductive layer.

7. The method according to claim 6, wherein said thin oxide layer has a thickness about within 10 angstroms.

8. The method according to claim 5, wherein said hemispherical silicon grains comprises forming on a top surface of said first conductive node.

9. A method for forming an electrode of a capacitor with a layer of hemispherical silicon grains, said method comprising:
providing a semiconductor structure having a dielectric layer thereon;
forming at least a polysilicon storage node on and in said dielectric layer;
forming an amorphous silicon layer at a sidewall of said polysilicon storage node; and
forming said layer of hemispherical silicon grains on said amorphous silicon layer.

10. A method according to claim 9, forming step of said amorphous silicon layer comprises:
depositing said amorphous silicon layer on said dielectric layer and said polysilicon storage node; and
etching back said amorphous silicon layer to remain partial said amorphous silicon layer at said sidewall of said polysilicon storage node.

11. The method according to claim 9, wherein said dielectric layer comprises an inter-silicon oxide layer.

12. The method according to claim 9, wherein said amorphous silicon layer has a thickness in a range about 50 to 900 angstroms.

13. A method for controlling a thickness of a layer of hemispherical silicon grains for an electrode, said method comprising:
providing a semiconductor structure having a dielectric layer thereon;
forming at least a conductive storage node on and in said dielectric layer, said conductive storage node primarily comprising silicon;
forming a thin oxide film over said dielectric layer and said conductive storage node;
forming an amorphous silicon layer at a sidewall of said conductive storage node; and
forming said layer of hemispherical silicon grains on said amorphous silicon layer and on a top surface of said conductive storage node.

14. The method according to claim 13, wherein said forming step of said amorphous silicon layer comprises:
depositing said amorphous silicon layer on said thin oxide film; and
etching back said amorphous silicon layer and said thin oxide film to remain partial said amorphous silicon layer and partial said thin oxide film at said sidewall of said conductive storage node.

15. The method according to claim 13, wherein said conductive storage node comprises an amorphous silicon storage node.

16. The method according to claim 13, wherein said thin oxide film comprises a silicon oxide film.

17. The method according to claim 16, wherein said silicon oxide film has a thickness smaller than 10 angstroms.

18. The method according to claim 13, wherein said amorphous silicon layer has a thickness in a range about from 50 through 900 angstroms.
